(19) United States
(12) Patent Application Publication
(10) Pub. No.: US 2020/0182935 A1
(43) Pub. Date: Jun. 11, 2020

(54) WEAR-MONITORING DEVICE OF A BRUSH OF A CURRENT-TRANSFERRING DEVICE IN AN ELECTRIC MACHINE

(71) Applicants: Robert Bosch GmbH, Stuttgart (DE); SEG Automotive Germany GmbH, Stuttgart (DE)

(72) Inventor: Istvan Deak, Ludwigsburg (DE)

(21) Appl. No.: 16/343,871

(22) PCT Filed: Oct. 27, 2017
(86) PCT No.: PCT/EP2017/077580

§ 371 Date: Apr. 22, 2019

(30) Foreign Application Priority Data
Oct. 27, 2016 (DE) 10 2016 221 226.5

(51) Int. Cl. G01R 31/34; G01R 31/66; H01R 13/66; H01R 39/58; H01R 39/08; H02K 11/20; H02K 23/66

(52) U.S. Cl. CPC G01R 31/343; G01R 31/66; H01R 13/6625; H02K 23/66; H01R 39/08; H02K 11/20; H01R 39/58

(57) ABSTRACT

The invention relates to a wear-monitoring device of a brush of a current-transferring device in an electric machine comprising a measuring element, which is arranged at a distance from the brush and forms an electrical capacitor together with the brush, the capacitance of which electrical capacitor depends on the position of the brush relative to the measuring element.

### BACKGROUND OF THE INVENTION

The invention relates to a wear-monitoring device of a brush of a current-transferring machine in an electric machine.

Current-transferring devices such as, for example, commutation devices in electric machines are used for transferring current to the armature of the electric machine and comprise brushes in brushholders to which current is supplied via litz wires. The brushes are pressed by a brush spring radially against the lateral surface of a collector rotating with the armature. Owing to the frictional contact with the collector lateral surface, the brushes are subjected to wear, which can be detected with the aid of a wear-monitoring device.

DE 197 55 232 A1 discloses a wear-monitoring device which comprises a signal transducer on the carbon brush, which signal transducer is moved toward an electrical bending contact, which is part of a signal circuit, when a preset wear limit for the brush is reached. Thereupon, a signal is triggered to indicate that the wear limit has been reached.

DE 10 2013 204 426 A1 discloses a wear-monitoring device in which the present position of an electrical conductor which is fixedly connected to the brush in detected, wherein a conclusion is drawn on the wear of the brush on the basis of the position of the electrical conductor.

### SUMMARY OF THE INVENTION

The wear-monitoring device according to the invention is used for monitoring the wear of a brush of a current-transferring device in an electric machine. The brush is accommodated displaceably in a brushholder and is pressed, owing to the force of a spring element, onto the lateral surface of an armature-side current-conducting component of the electric machine, via which component current is transferred to an armature winding. The supply of current to the brush takes place by means of an electrical conductor, which is either connected to a current source or connected electrically to ground

The current-transferring device is, for example, a commutation device comprising an armature-side collector for current transfer and commutation, with the brush resting against the cylindrical lateral surface of said collector and being pressed radially against the lateral surface of the collector by the spring element. The collector has collector laminations which are electrically connected to the armature windings. Such commutation devices are preferably used in DC motors.

The current-transferring device can also, in accordance with an alternative embodiment, be in the form of a slipring system in a slipring rotor machine. Current is transferred to an armature winding via an armature-side slipring, against which the brush rests. The slipring rotor machine is an AC asynchronous machine which is used as a generator, for example.

Owing to the frictional contact between the end side of the brush accommodated displaceably in the brushholder and the rotating, armature-side component, the brush is subjected to permanent wear. With the aid of the wear-monitoring device according to the invention, the wear of the brush can be monitored and in particular a critical wear limit can be detected.

The wear-monitoring device comprises a current-conducting measuring element assigned to the brush, said measuring element having an electrical voltage which is dependent on the position of the brush in the brushholder. If the position of the brush in the brushholder changes, the electrical voltage of the current-conducting measuring element also changes, which can be detected with the aid of an electrical measuring device of the wear-monitoring device.

The electrical measuring element is arranged at a distance from the brush and, together with the brush, forms an electrical capacitor having an electrical capacitance which is dependent on the relative position of the brush with respect to the measuring element. The brush and the measuring element therefore each form capacitor halves, between which, owing to energization of the brush, an electrical field and, associated therewith, a voltage potential is produced in the measuring element, which can be detected with the aid of the measuring device.

This embodiment has the advantage that a contactless, capacitive measurement is performed and no contact is required between the measuring element and the brush. The measuring element is at a distance from the brush and there is no contact between the measuring element and the brush. Correspondingly, there is also no contamination or corrosion of the measuring element which could result in the operation of the wear-monitoring device being impaired.

In accordance with a preferred embodiment, the measuring element is arranged fixed to the housing and cannot perform a relative movement with respect to the housing. In the event of wear, the length of the brush and therefore also the relative position of the brush with respect to the measuring element changes, as a result of which the capacitance of the electrical capacitor, consisting of the brush and the measuring element, changes, which results in a correspondingly changed electrical voltage in the measuring element, which can be determined with the aid of the measuring device.

The measuring element is arranged either on a housing component of the current-transferring device or, in accordance with a preferred embodiment, in or on a brushholder, in which the brush is guided displaceably and which advantageously also accommodates the spring element, which causes the brush to impinge on the lateral surface of the brushholder. For example, the measuring element can be integrated in the wall of the brushholder, which consists of an electrically nonconductive material. This embodiment has the advantage that the measuring element is located in the immediate vicinity of the brush and therefore a significant electrical field can be formed between the measuring element and the brush without there being the risk of a direct contact between the measuring element and the brush resulting in a short circuit.

In accordance with a further advantageous embodiment, in the unused state, the brush has at least 50% of the area of the measuring element. It may be expedient, if appropriate, for the area of the brush in the unused state to have at least 90%, for example 95%, of the facing area of the measuring element, based on the mutually facing and opposite side faces of the measuring element and the brush. In the unused initial state, the measuring element and the brush are advantageously opposite one another in order to achieve a comparatively high capacitance of the capacitor. Correspondingly, the brush and the measuring element have a high degree of overlap in the initial state of the brush. During wear of the brush, the brush changes its relative position with respect to the measuring element, as a result of which the proportion of the area of the brush which is opposite the measuring element decreases and the capacitance of the capacitor changes.

In accordance with a further expedient embodiment, the measuring element partially or completely envelops the brush. Thus, it may be expedient, for example, in the case of integration of the measuring element in the brushholder, which preferably has a rectangular cross-sectional geometry for accommodating the brush, for the measuring element to be arranged in or on precisely one side of the brushholder, on two sides, on three sides or on four sides. In the case of positioning on all four sides, the measuring element completely envelops the inner brush, whereas in the case of positioning on two or three sides, the measuring element only partially envelops the brush, and in the case of positioning on only one side, the measuring element is opposite the brush. Expediently, the measuring element is integrated in the wall of the brushholder so that direct contact between the brush and the measuring element is prevented.

The measuring element is, for example, in the form of an electrical plate, which is opposite the brush and in particular is arranged parallel to the brush. In the case of partial or complete envelopment, in each case electrical plates are integrated in the various walls of the brushholder, said electrical plates being connected to one another and together forming the measuring element.

In accordance with yet a further expedient embodiment, the wear-monitoring device has a drive circuit for generating a field voltage in the brush. A field voltage signal is generated in the brush by the drive circuit, wherein, owing to the capacitive coupling between the brush and the measuring element, a corresponding voltage characteristic is also set in the measuring element, and this voltage characteristic can be determined via the electrical measuring device, which is advantageously likewise part of the wear-monitoring device. As field voltage signal, a PWM-type (pulse width modulation) field voltage having a rectangular voltage characteristic is generated, for example, and this voltage characteristic is also set in the measuring element.

The electrical connection between the measuring element and a measuring device in the form of evaluation electronics is provided by means of a lead frame, for example. The drive circuit is in the form of a field regulator, for example, which comprises a transistor, for example a MOSFET, or an H bridge, wherein a defined voltage signal is provided to the brush via the drive circuit.

The measured voltage in the measuring element can be set in relationship with respect to the operating voltage applied to the brush for energizing the armature winding.

In accordance with a further expedient embodiment, the operating voltage is used as field voltage. The voltage set in the measuring element has a known relationship with respect to the operating voltage in the brush, wherein in the case of wear of the brush, a change in voltage is set in the measuring element, caused by a change in the capacitance.

### BRIEF DESCRIPTION OF THE DRAWINGS

Further advantages and expedient embodiments are set forth in the further claims, the description of the figures and the drawings, in which:

FIG. 1 shows a schematic illustration of a brush in a brushholder of a current-transferring device in an electric machine, illustrated in the unused initial state and in a state with wear, in each case with an assigned measuring element,

FIG. 2 shows the characteristic of a field voltage and the characteristic of the voltage in the measuring element in response to the field voltage, illustrated in the initial state and in the state with wear of the brush,

FIG. 3 shows illustrations corresponding to FIG. 1 of the brush in the initial state and with wear, but with three assigned measuring elements on the brushholder,

FIG. 4 shows illustrations corresponding to FIG. 2 of the field voltage and the response voltage in the first measuring element,

FIGS. 5 to 8 show, in cross section, a brush in a brushholder with various variant embodiments of a measuring element,

FIG. 9 shows a drive circuit for generating a field voltage.

### DETAILED DESCRIPTION

Identical parts have been provided with the same reference symbols in the figures.

FIG. 1 shows, in two different states of wear, a brush 1 in a brushholder 2 of a current-transferring device in an electric machine. Armature windings are energized with the aid of the current-transferring device. The current-transferring device is, for example, a commutation device comprising a collector 3 rotating with the armature, with the brush 1 resting against the lateral surface of said collector. The brush 1 is mounted displaceably in the brushholder 2 and is pressed against the lateral surface of the collector 3 by a spring element 4, which is supported on the base of the brushholder 2. Owing to the frictional contact between the end side of the brush 1 and the lateral surface of the collector 3, the brush is subjected to wear. In FIG. 1, the top image shows the brush in the unused initial state, and the bottom image shows the brush in the state of wear in which the brush length is reduced in comparison with the unused state. The brush 1 is energized by means of an electrical conductor 5.

In order to be able to detect the present state of wear and possibly to generate a warning signal when a wear limit is reached, the current-transferring device is provided with a wear-monitoring device, which comprises a current-conducting measuring element 6 which is assigned to the brush 1. The measuring element 6 is in the form of, for example, an electrical conductor or a current-conducting plate and is arranged at a distance from the brush 1, but parallel thereto. The measuring element 6 is positioned, for example, in the wall of the brushholder 2. In any case, direct contact between the brush 1 and the measuring element 6 is ruled out.

The brush 1 and the current-conducting measuring element 6 each form capacitor halves and together form an electrical capacitor having a capacitance which is dependent on the relative position between the brush 1 and the measuring element 6. The measuring element 6 is arranged fixed to the housing, in particular is fixedly connected to the brushholder 2, in particular is integrated in the wall of the brushholder 2. As the degree of wear increases, the length of the brush 1 is shortened, as a result of which the relative position between the brush 1 and the measuring element 6 changes. As a result, a changing capacitance of the capacitor comprising the capacitor halves comprising the brush 1 and the measuring element 6 is also set.

The change in capacitance of the capacitor comprising the brush 1 and the measuring element 6 can be detected via the electrical voltage potential U₁ of the measuring element 6. An electrical field E is produced between the brush 1 and the measuring element 6, and this electrical field generates the voltage potential U₁ in the measuring element 6. The voltage U₁ of the measuring element 6 can be determined with the aid of an electrical measuring device. In the event of a change in the voltage U₁, triggered by a change in the capacitance owing to a wear-related shortening and position change of the brush 1, a warning signal can be generated as soon as the voltage U₁ of the measuring element 6 reaches a threshold value.

The measuring element 6 is arranged axially at a distance from the open end side of the brushholder or the collector 3. In the unused initial state of the brush 1, said brush has a greater length than the measuring element 6 and is arranged opposite the measuring element 6 in such a way that the brush 1 extends completely to the height of the measuring element 6. In the used state of wear shown in the image at the bottom in FIG. 1, on the other hand, the brush 1 has been displaced so far in the direction of the collector 3 owing to wear that there is only a partial overlap between the brush 1 and the measuring element 6, as a result of which there is a lower electrical capacitance.

In the exemplary embodiment shown in FIG. 1, the electrical measuring device comprises precisely one measuring element 6, which is arranged so as to be fixed to the housing or on the brushholder 2.

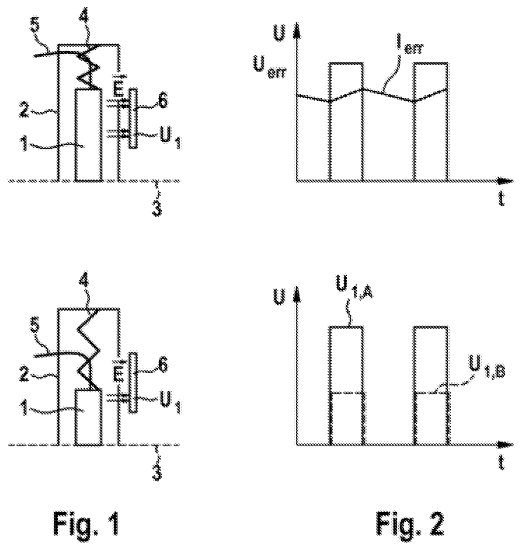

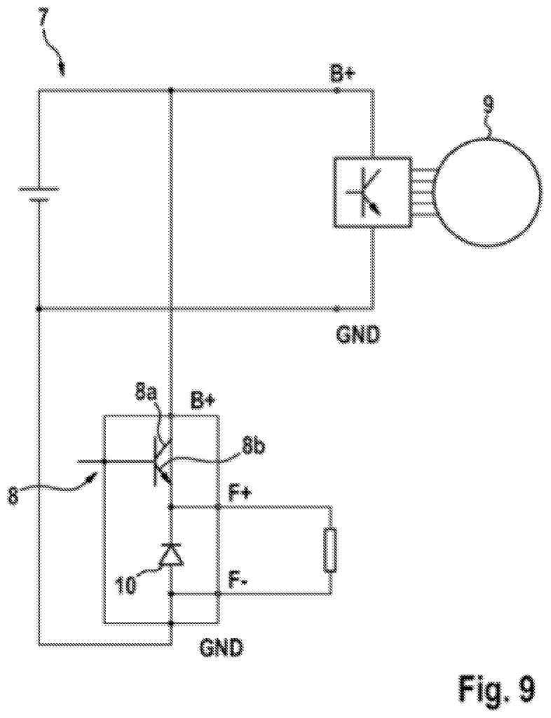

FIG. 2 shows voltage characteristics U for a field voltage Uₑᵣᵣ (top image) and a measuring element voltage U₁ (bottom image) over time. The field voltage Uₑᵣᵣ is applied to the brush 1, for example with the aid of a drive circuit, as illustrated in FIG. 9. The field voltage Uₑᵣᵣ is in the form of a rectangular PWM (pulse width modulation) signal, which results in the field current characteristic Iₑᵣᵣ illustrated in the top graph. Owing to the capacitive coupling between the brush 1, to which the field voltage Uₑᵣᵣ is applied, and the measuring element 6, the measuring element voltage U₁ is set in accordance with the bottom graph. The graph at the bottom shows the measuring element voltage U_{L}A for the unused initial state of the brush 1 and the measuring element voltage U_{1,B} for a brush which, as shown in the image at the bottom in FIG. 1, has been reduced owing to wear. In the unused initial state, the measuring element voltage U_{1,A} is greater than in the used state in accordance with the measuring element voltage U_{1,B}. This difference can be detected via the measuring device, wherein the warning signal is generated as soon as the measuring element voltage falls below a threshold value.

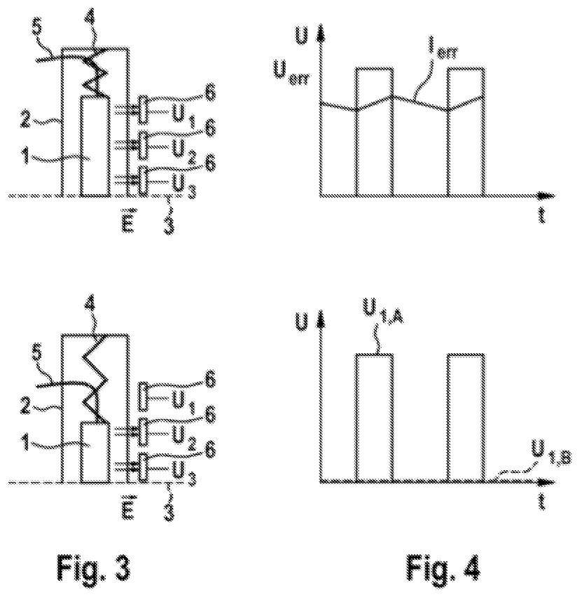

FIG. 3 shows a variant embodiment having a plurality of, in particular three, electrically conductive measuring elements 6 arranged one above the other which each form, with the brush 1, a capacitor. Each capacitor, consisting of the brush 1 and one of the measuring elements 6, has a specific capacitance, which is, however, dependent on the relative position of the brush 1 in the brushholder 2 and with respect to each measuring element 6.

The top graph in FIG. 4 shows the field voltage Uₑᵣᵣ and the field current Iₑᵣᵣ, which are identical to the field voltage and the field current in FIG. 2. The field voltage Uₑᵣᵣ is in the form of a rectangular PWM signal.

The bottom graph in FIG. 4 shows the measuring element voltage U₁ for the first measuring element. The voltages of the further measuring elements are denoted by U₂ and U₃. As can be seen from the graph, the measuring element voltage U_{1,A} in the unworn initial state has been provided with a high amplitude, whereas in the used state of the brush 1 in which said brush has a shortened length, the measuring element voltage U_{1,B} drops to zero. As shown in the image at the bottom in FIG. 3, the brush 1 has been shortened to such an extent that there is no longer any overlap with the measuring element 6 above, with the result that, correspondingly, the electrical capacitance drops to zero and the measuring element voltage U_{1,B} is likewise zero. This complete drop to zero can be detected, as is likewise true for the second measuring element with the measuring element voltage U₂ and the third measuring element with the measuring element voltage U₃. A warning signal is generated, for example, as soon as the measuring element voltage U₂ or the measuring element voltage U₃ drops to zero.

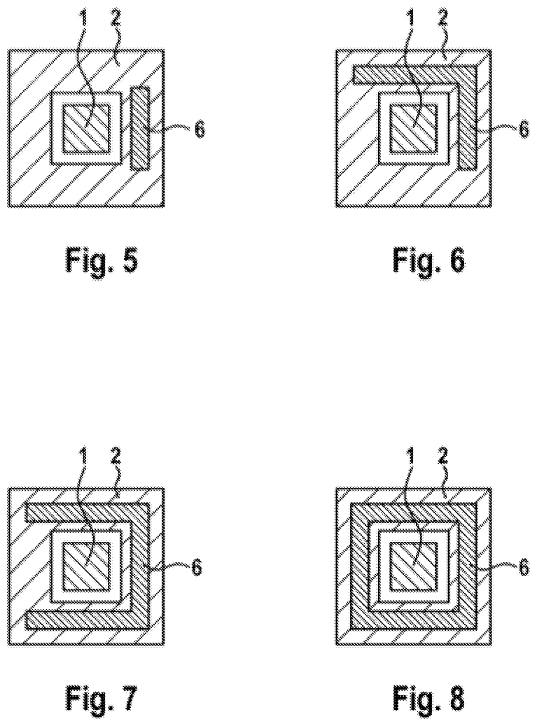

FIGS. 5 to 8 show various variant embodiments for the measuring element 6. All of the variant embodiments have the common feature that the measuring element 6 is completely integrated in the wall of the brushholder 2 and there is thus no touching contact with the brush 1.

As shown in FIG. 5, the measuring element 6 extends in the form of a plate only on one side of the brushholder 2 and is opposite the brush 1. In FIG. 6, the measuring element 6 is angular and is opposite the brush 1 on two sides. In FIG. 7, the measuring element 6 is U-shaped and is opposite the brush 1 on three sides. In FIG. 8, the measuring element 6 is formed all round in rectangular form and completely surrounds the brush 1 so that the measuring element 6 is opposite the brush 1 on all sides.

FIG. 9 shows a drive circuit 7 for generating a field voltage Uₑᵣᵣ in the brush. The drive circuit 7 comprises a transistor 8, for example a MOSFET, with the drain 8a thereof being connected to the voltage B+ of a voltage source 9, whereas the source 8b of the transistor is connected to the positive terminal F+ of a rotor or armature winding via a brush. The negative terminal F− of the armature winding is connected to ground GND via a further brush. A freewheeling diode 10 in the reverse direction is connected in parallel with the armature winding. The transistor is driven by a clocked signal, wherein the level of the field current or the field voltage can be set via the duty cycle of this signal.

The drive circuit 7 can also, if appropriate, be provided with an H bridge, which opens up the possibility of further functions in the field circuit.

1. A wear-monitoring device of a brush (1) of a current-transferring device in an electric machine, in which wear of the brush (1) is determinable depending on a position of the brush (1) in a brushholder (2), the wear-monitoring device comprising a current-conducting measuring element (6) assigned to the brush (1), said measuring element having an electrical voltage which is dependent on the position of the brush (1) in the brushholder (2), characterized in that the measuring element (6) is arranged at a distance from the brush (1) and, together with the brush (1), forms an electrical capacitor having an electrical capacitance which is dependent on the relative position of the brush (1) with respect to the measuring element (6).

2. The wear-monitoring device as claimed in claim 1, characterized in that the measuring element (6) is arranged fixedly in or on a brushholder (2), in which the brush (1) is guided displaceably.

3. The wear-monitoring device as claimed in claim 2, characterized in that the measuring element (6) is integrated in a wall of the brushholder (2).

4. The wear-monitoring device as claimed in claim 1, characterized in that the measuring element (6) partially or completely envelops the brush (1).

5. The wear-monitoring device as claimed in claim 1, characterized in that the measuring element (6) is in the form of an electrical plate which is arranged opposite, the brush (1).

6. The wear-monitoring device as claimed in claim 1, characterized in that, in an unused state, the brush (1) has at least 50% of an area of the measuring element (6).

7. The wear-monitoring device as claimed in claim 1, characterized in that the current-transferring device is in the form of a commutation device.

8. The wear-monitoring device as claimed in claim 1, characterized in that the current-transferring device is in the form of a slipring system in a slipring rotor machine.

9. The wear-monitoring device as claimed in claim 1, comprising a drive circuit (7) for generating a field voltage in the brush (1).

10. A method for operating a wear-monitoring device as claimed in claim 9, the method comprising generating a PWM-type field voltage in the drive circuit (7).

11. A current-transferring device comprising a wear-monitoring device as claimed in claim 1.

12. An electric machine comprising a current-transferring device as claimed in claim 11.

13. The wear-monitoring device as claimed in claim 1, characterized in that the measuring element (6) is in the form of an electrical plate which is arranged parallel to and opposite the brush (1).

14. The wear-monitoring device as claimed in claim 1, characterized in that, in an unused state, the brush (1) has at least 90% of an area of the measuring element (6).
